(19) United States
(12) Patent Application Publication
(10) Pub. No.: US 2008/0123306 A1
(43) Pub. Date: May 29, 2008

(54) Circuit board back plate

(76) Inventor: Ted Ju, Keelung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/907,138

(22) Filed: Oct. 10, 2007

(30) Foreign Application Priority Data
Nov. 23, 2006 (CN) 200620067999.2

(51) Int. Cl. H05K 5/00

(52) U.S. Cl. 361/757

(57) ABSTRACT

A back plate can be connected to a circuit board, and the back plate comprises a plastic member with metal elements fixed onto it, and the metal elements have threaded holes for fixing the plastic member onto the circuit board. Compared to the prior art, the back plate has metal elements which increase the strength of the back plate. In addition, the plastic member is fixed onto the circuit board by means of threaded holes in the metal elements without the use of screw-nuts so as to reduce weight, simplify manufacturing, and reduce the costs of the back plate.

### BACKGROUND OF THE INVENTION

1. Field of the Invention

The present invention relates to a back plate for a circuit board cooling device.

2. Description of the Prior Art

Due to increased data processing speed and longer computer operation times, the amount of heat produced by the central processing unit of the computer is also increasing. Hence, it is necessary to use a heat-dissipating device to dissipate the heat produced by the central processing unit. And in order to facilitate installation of the heat-dissipating device to the printed circuit board and enhance the strength of the printed circuit board, a back plate is employed. Up to the present, commonly used back plates can be classified into two types. One type is entirely made of plastic and the other type is made of metal. The former is easy to manufacture and incurs lower costs compared to the latter, but provides lower strength and is thus limited in its application. The metal back plate provides higher strength but is heavier and incurs higher costs.

Being aware of theses shortcomings of the presently available back plates, the author of the present invention has devoted special efforts to the research of this field. As a result the present invention is presented which effectively resolves the above mentioned problems.

### SUMMARY OF THE INVENTION

It is a primary object of the present invention to provide a back plate made of plastic that has metal elements so as to enhance the strength and rigidity of the back plate while reducing its costs compared to those of a back plate made entirely from metal.

For achieving the objective stated above, the back plate can be mounted to a circuit board, and the back plate comprises a member and metal elements fixed onto the board, and the metal elements have threaded holes for fixing the structure onto the circuit board.

Compared to the prior art, the back plate's strength is increased by the metal elements. In addition, the structure is fixed onto the circuit board by means of threaded holes in the metal elements, eliminating the need for screw-nuts and thus reducing weight, simplifying manufacture, and reducing the costs of the back plate.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The above and further advantages of this invention may be better understood by referring to the following description, taken in conjunction with the accompanying drawings, in which:

FIG. 1 is an exploded perspective view of a back plate according to the present invention;

FIG. 2 is an exploded perspective view of the back plate of FIG. 1 from another view angle;

FIG. 3 is a perspective view of the assembled back plate of FIG. 1;

FIG. 4 is a schematic view of the plastic member of the back plate of FIG. 1;

FIG. 5 is a partial enlarged view of FIG. 4; and

FIG. 6 is a schematic view of a metal element of the back plate of FIG. 1.

The drawings will be described further in connection with the following Detailed Description of the Invention.

### DETAILED DESCRIPTION OF THE PREFERRED EMBODIMENTS

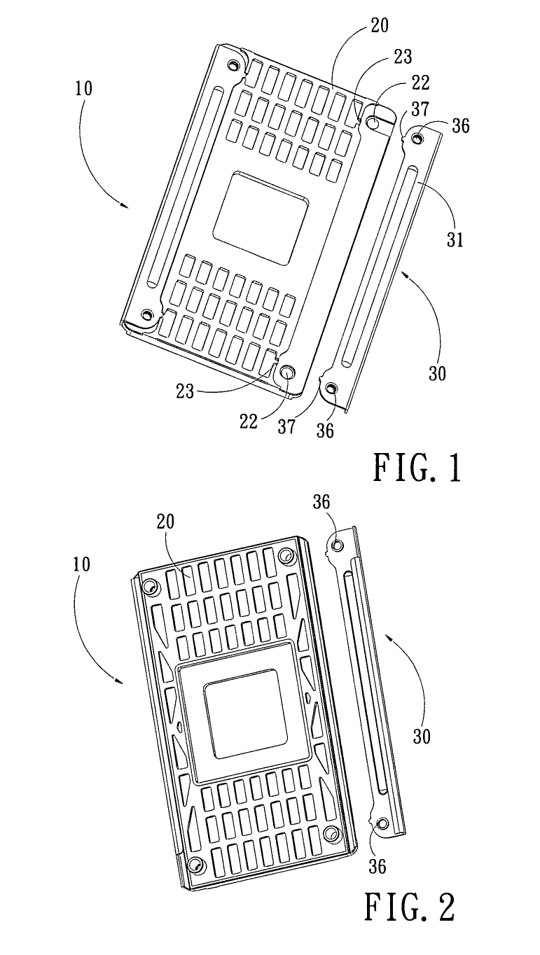

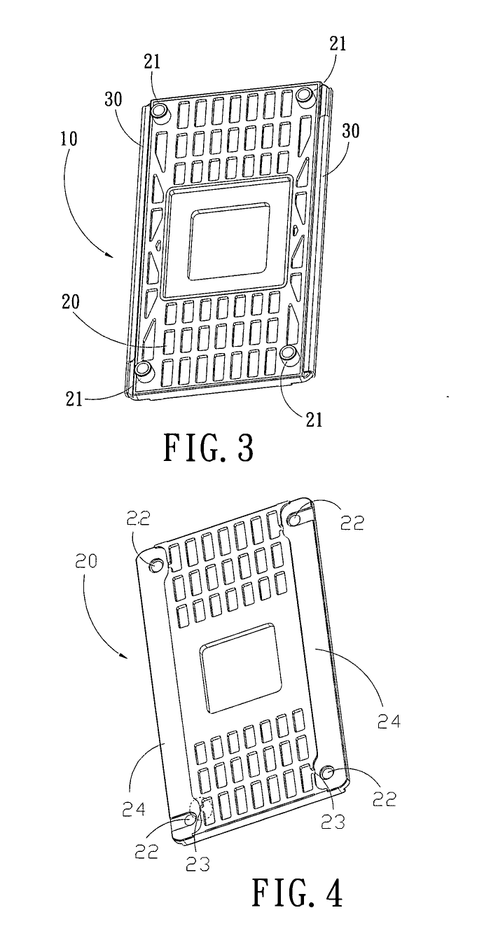

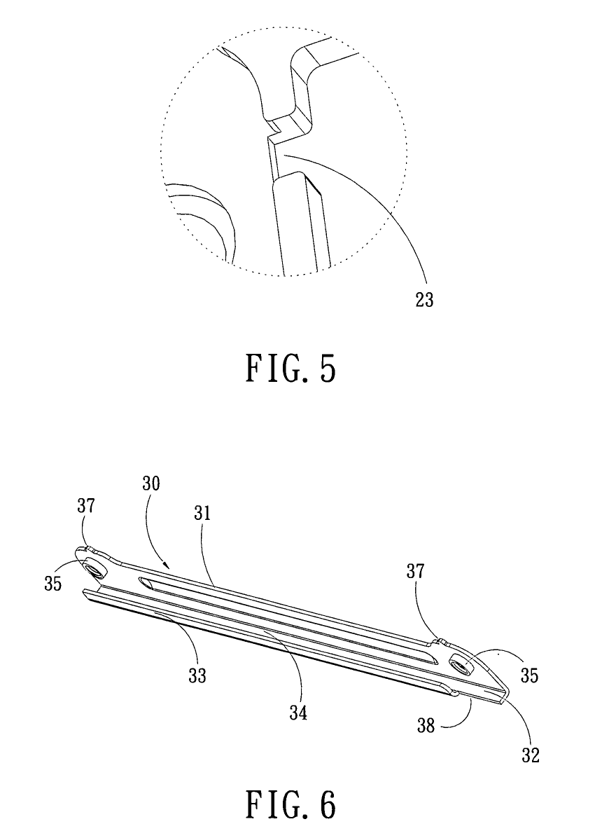

Please refer to FIG. 1 to FIG. 6. The back plate 10 can be connected to a circuit board (not shown). The back plate 10 comprises a plastic member 20 and two metal elements 30 mounted on the two sides of the plastic member 20 to enhance the strength and rigidity of the back plate 10.

The plastic member 20 is shaped approximately in a rectangular structure with a central hole. The plastic member 20 has a plurality of lateral holes in order to prevent the plastic member 20 bending. The plastic member 20 has four positioning sleeves 21 with a defined height on its four corners for hooking the back plate 10 into respective holes (not shown) of the circuit board. The plastic member 20 is penetrated by the positioning sleeves 21 forming positioning holes 22, and positioning grooves 23 are respectively provided near each of the positioning holes 22. There are two clamping edges 24 on two sides of the plastic member 20, these clamping edges 24 being thinner than the middle part of the plastic member 20. The clamping edges 24 are penetrated by the positioning sleeves 21 and embraced by the metal elements 30, thus enhancing the strength and rigidity of the plastic member 20.

Each of the metal elements 30 is integrally formed with metal, and the length of the metal element 30 is less than or equal to the length of the plastic member 20. Each of the metal elements 30 includes an upper arm 31, a lower arm 33, and a connecting portion 32 connecting the upper arm 31 to the lower arm 33. There is receiving space 34 between the upper arm 31, the lower arm 33, and the connecting portion 32. The clamping edges 24 fit tightly into the receiving space 34 between the upper arm 31 and lower arm 33 thus fixing the plastic member 20 to the metal elements 30 so as to enhance the strength and rigidity of the back plate 10. Two fixation sleeves 35 are formed at the two ends of the upper arm 31 and correspond to the positioning holes 22 of the plastic member 20. The fixation sleeves 35 fit into the positioning holes 22 and are threaded inside, thus forming threaded holes 36 so that screws (not shown) can be passed through the fixation holes 35 of the circuit board (not shown) to fix the back plate 10 to the circuit board. Hence, no screw-nuts are needed to fix the circuit board onto the plastic member 20, thereby reducing costs and making the back plate 10 suitable for mass production. The upper arm 31 of the metal elements 30 has positioning blocks 37 used to engage with the positioning grooves 23 in the plastic member 20. The positioning blocks 37 of the metal elements 30 are matched with the positioning grooves 23 of the plastic member 20 in order to prevent relative motion between the plastic member 20 and the metal elements 30. The lower arm 33 is shorter than the upper arm 31 and thus forms a recess 38 at the position of one of the fixation sleeves 35. The recess 38 is used to conveniently insert the corresponding fixation sleeve 35 into the positioning hole 22 of the plastic member 20, followed by inserting the other fixation sleeve 35 into its corresponding positioning hole 22. First, the fixation sleeve 35 corresponding to recess 38 is placed in positioning hole 22 of the plastic member 20, and then the metal element 30 is rotated around the fixation sleeve 35 so that the other fixation sleeve 35 can be inserted into the other positioning hole 22 of the plastic member 20. Then, the back plate 10 is compressed by a machine (not shown) to lock the positioning blocks 37 of the metal elements 30 in the positioning grooves 23 of the plastic member 20, thus completing the assembly of the back plate 10. Finally, the back plate 10 is installed onto the circuit board.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A back plate mounted to a circuit board, comprising a plastic member and metal elements fixed onto the plastic member, the metal elements having threaded holes for fixing the plastic member onto the circuit board.

2. The back plate as claimed in claim 1, wherein the metal elements are installed on two sides of the plastic member.

3. The back plate as claimed in claim 1, wherein the plastic member comprises a plurality of positioning holes and the metal elements comprise a plurality of fixation sleeves corresponding to the positioning holes.

4. The back plate as claimed in claim 3, wherein the inner walls of the fixation sleeves are threaded.

5. The back plate as claimed in claim 1, wherein the plastic member has a plurality of positioning grooves and the metal elements have a plurality of positioning blocks mated with the positioning grooves.

6. The back plate as claimed in claim 5, wherein the positioning blocks are formed by protruding from one side of the metal elements.

7. The back plate as claimed in claim 1, wherein the metal element comprises an upper arm, a lower arm, and a connecting portion used to connect the upper arm and the lower arm.

8. The back plate as claimed in claim 7, wherein the metal elements have fixation sleeves and the lower arm has a recess corresponding to one of the fixation sleeves.

9. The back plate as claimed in claim 1, wherein the length of the metal elements is less than or equal to the length of the plastic member.

10. The back plate as claimed in claim 1, wherein the plastic member has a plurality of positioning sleeves to engage with the circuit board.
